(19) United States
(12) Patent Application Publication
(10) Pub. No.: US 2020/0168450 A1
(43) Pub. Date: May 28, 2020

(54) METHOD FOR FABRICATING INTERCONNECT OF SEMICONDUCTOR DEVICE

(71) Applicant: United Microelectronics Corp., Hsinchu (TW)

(72) Inventors: Ko-Wei Lin, Taichung City (TW); Kuan-Hsiang Chen, Nantou County (TW); Hsin-Fu Huang, Tainan City (TW); Chun-Ling Lin, Tainan City (TW); Sheng-Yi Su, Kaohsiung City (TW); Pei-Hsun Kao, Kaohsiung City (TW)

(73) Assignee: United Microelectronics Corp., Hsinchu (TW)

(21) Appl. No.: 16/203,212

(22) Filed: Nov. 28, 2018

(51) Int. Cl. H01L 21/02; H01L 21/285; H01L 21/768

(52) U.S. Cl. CPC H01L 21/0206; H01L 21/76855; H01L 21/76843; H01L 21/28556

(57) ABSTRACT

A method for fabricating interconnect of semiconductor device. The method includes providing a base substrate, having an inter-layer dielectric layer on top. A copper interconnect structure is formed in the inter-layer dielectric layer. A pre-sputter clean process is performed with hydrogen radicals on the copper interconnect structure. A degas process is sequentially performed on the copper interconnect structure. A cobalt cap layer is formed on the copper interconnect structure.

### BACKGROUND

### 1. Field of the Invention

The present invention generally relates to semiconductor fabrication technology, and particularly to a method for fabricating interconnect of semiconductor device.

### 2. Description of Related Art

An integrated circuit includes a large number of working devices, such as transistors, memory cells or any functional devices. The working devices are distributed horizontally and vertically based on the semiconductor fabrication layout. To connect the working devices to form a functional circuit, an interconnect is needed for proper connection between the working devices. The interconnect structure usually includes plugs and/or connection lines as known in the art.

Basically, to improve the conductivity, the interconnect usually is made of metal, such as copper. The interconnect depending on the layout of the working devices may include multiple levels. One interconnect layer may connect to another interconnect layer by stacking on. However, to improve the quality of interconnect at the contact surface, a cobalt cap layer may be additionally formed on the surface. In a usual way, a pre-clean process is usually taken on the copper surface and the cobalt cap layer is formed on the cleaned surface of the interconnect.

However, a poor quality of the cobalt cap layer may in contrary effect reduce the performance of the interconnect. It is needed to improve the formation quality of the cobalt cap layer in fabrication.

### SUMMARY OF THE INVENTION

The invention provides a method for fabricating interconnect of semiconductor device, in which a pre-sputter clean process may be included to provide a proper condition to form the cobalt cap layer on a copper interconnect structure.

In an embodiment, the invention provides a method for fabricating interconnect of semiconductor device. The method includes providing a base substrate, having an inter-layer dielectric layer on top. A copper interconnect structure is formed in the inter-layer dielectric layer. A pre-sputter clean process is performed with hydrogen radicals on the copper interconnect structure. A degas process is sequentially performed on the copper interconnect structure. A cobalt cap layer is formed on the copper interconnect structure.

In an embodiment, as to the method for fabricating interconnect, the degas process includes argon gas.

In an embodiment, as to the method for fabricating interconnect, the degas process is operated at a temperature in a range of 380° C. to 450° C.

In an embodiment, as to the method for fabricating interconnect, the degas process is operated at a temperature of 400° C.

In an embodiment, as to the method for fabricating interconnect, the step of providing the base substrate comprises providing a substrate; forming the inter-layer dielectric layer over the substrate; patterning the inter-layer dielectric layer to have an indent structure; forming a barrier layer on a sidewall and a bottom of the indent structure. Further, the method comprises plating a copper layer over the inter-layer dielectric layer, wherein a portion of the copper layer is also filled into the indent structure and performing a polishing process until the inter-layer dielectric layer is exposed. A portion of the copper layer in the indent structure forms the copper interconnect structure.

In an embodiment, as to the method for fabricating interconnect, the method further comprises forming a seed layer on the barrier layer before the step of plating the copper layer.

In an embodiment, as to the method for fabricating interconnect, the indent structure comprises a trench or an opening.

In an embodiment, as to the method for fabricating interconnect, the pre-sputter clean process comprises forming a plasma containing the hydrogen radicals and filtering the plasma to pass the hydrogen radicals out onto the copper interconnect structure.

In an embodiment, as to the method for fabricating interconnect, the pre-sputter clean process is performed at a temperature of 300° C. or higher.

In an embodiment, as to the method for fabricating interconnect, the pre-sputter clean process is performed at a temperature of 310 ° C.

In an embodiment, as to the method for fabricating interconnect, the pre-sputter clean process dominantly cleans moisture and CuO on the copper interconnect structure while hydrogen compounds are not induced yet by the degas process.

In an embodiment, as to the method for fabricating interconnect, the degas process cleans hydrogen compound potentially induced by the pre-sputter clean process.

In an embodiment, as to the method for fabricating interconnect, the degas process also clean a residue from the polishing process.

In an embodiment, as to the method for fabricating interconnect, the copper interconnect structure comprises a copper plug.

In an embodiment, as to the method for fabricating interconnect, the copper interconnect structure comprises an interconnect line.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a drawing, schematically illustrating the method for fabricating an interconnect structure of semiconductor device as looked into, according to an embodiment of the invention.

FIG. 2 is a drawing, schematically illustrating the method for fabricating an interconnect structure of semiconductor device as looked into, according to an embodiment of the invention.

FIG. 3 is a drawing, schematically illustrating the method for fabricating an interconnect structure of semiconductor device, according to an embodiment of the invention.

### DESCRIPTION OF THE EMBODIMENTS

The invention is directed to semiconductor fabrication technology to form copper interconnect structure. The invention involving formation of a cobalt cap layer on the copper interconnect structure with improve quality. The cobalt cap layer may cover the copper interconnect structure at the predetermined surface to reduce the resistance when other metal layer contacts with the copper interconnect structure. The invention may at least improve the cobalt cap layer with less probability about inducing opening or crack in the cobalt cap layer.

Due to the property of cobalt material, cobalt cap layer may be formed by a maskless manner because cobalt material in deposition has a selectivity in physical phenomenon to be formed on the copper surface but not on the inter-layer dielectric layer, in which the copper interconnect structure is formed in the inter-layer dielectric layer with a boundary between them.

The invention has provided multiple embodiments for describing the invention but the invention is not just limited to the embodiments as provided.

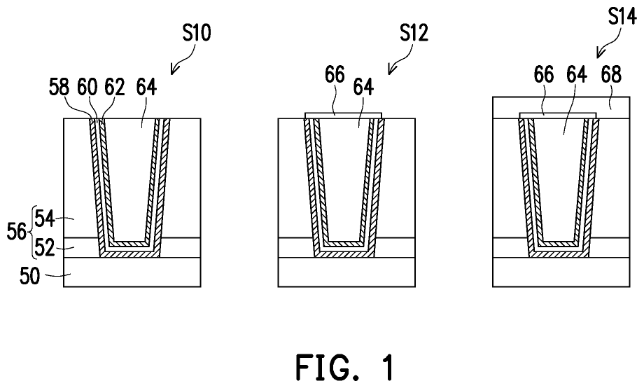

FIG. 1 is a drawing, schematically illustrating the method for fabricating an interconnect structure of semiconductor device as looked into, according to an embodiment of the invention.

Referring to FIG. 1, in step S10, the invention has looked into the fabrication processes to form a copper interconnect structure with cobalt cap layer in an ideal design. A base substrate is provided, having an inter-layer dielectric layer 56 on top. In better detail as an example, the inter-layer dielectric layer 56 is formed on a substrate 50. The inter-layer dielectric layer 56 may include an etching stop layer 52 and a dielectric layer 54 in stack but the invention is not just limited to a specific stack of the inter-layer dielectric layer 56. A copper interconnect structure 64 is ideally as designed formed in the inter-layer dielectric layer 56.

Here, the copper interconnect structure 64 may be a plug or an interconnection line, in which the cross-sectional structure is the same. In an embodiment, a copper plug may fill into an opening in the inter-layer dielectric layer 56. In an embodiment, a copper interconnection line may fill into a trench in the inter-layer dielectric layer 56. However, the cross-section view for both of plug and the interconnection line are similar.

The copper interconnect structure 64 is usually formed by electric plating. To have better quality for the copper interconnect structure 64, the copper interconnect structure 64 may further include a barrier layer 58, a cobalt liner layer 60 and a seed layer 62, as such the plating process with the seed layer 62 can be performed to form the copper interconnect structure 64. In other words, the interconnect structure 64 may include the barrier layer 58, the cobalt liner layer 60 and the seed layer 62 in better detail, but the invention is not just limited to the embodiments.

In step S12, a cobalt cap layer 66 is formed on the copper interconnect structure 64. Due to the selectivity in deposition of the cobalt material with respect to materials of copper and dielectric, respectively, the cobalt cap layer can be formed without a mask in an example.

In step S14, for the subsequent fabrication processes, another dielectric layer, such as an etching stop layer 68 may be further formed thereon.

As described, the cobalt cap layer 66 is expected to be formed on the copper interconnection structure 64. The quality of the interconnection structure 64 as a whole may be determined involving the quality of the cobalt cap layer 66.

Additionally, to form the copper interconnection structure 64, in an embodiment, the method may include providing a substrate 50; forming the inter-layer dielectric layer 56 over the substrate 50; patterning the inter-layer dielectric layer 56 to have an indent structure; forming a barrier layer on a sidewall and a bottom of the indent structure; plating a copper layer over the inter-layer dielectric layer, wherein a portion of the copper layer is also filled into the indent structure; and performing a polishing process until the inter-layer dielectric layer is exposed.

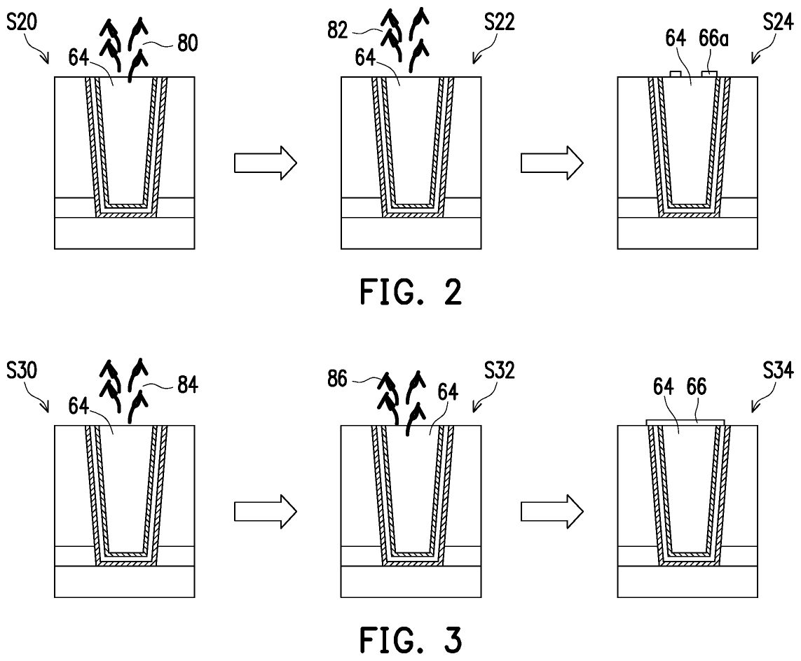

FIG. 2 is a drawing, schematically illustrating the method for fabricating an interconnect structure of semiconductor device as looked into, according to an embodiment of the invention.

Referring to FIG. 2, the invention has further looked into the issue to form the cobalt cap layer 66 on the interconnection structure 64. In step S20, before depositing the cobalt material onto the copper interconnect structure 64, the surface to be formed with the cobalt cap layer 66 usually needs be a pre-cleaning process. In a manner, the pre-cleaning process includes two stages. In first cleaning stage as to the step S20, a degas process is performed on the copper interconnect structure 64. The degas process in this example is mainly to removed H₂O. The temperature in an example is about 310° C. with hydrogen gas.

In step S22, the second cleaning stage is performed to further remove CuO and the polishing residue on the copper interconnection structure 64. The polishing residue in an example is chemical mechanical polishing (CMP) process to polishing a portion of the preliminary copper material on the inter-layer dielectric layer 56 so to have the copper interconnection structure 64.

In step S24, sequentially to the step S22, the cobalt material is deposited on to the copper interconnection structure 64 without a mask. As a result, a cobalt cap layer 66a is formed on the copper interconnection structure 64. As observed by the invention, the cobalt cap layer 66a may be not fully covering on the copper interconnection structure 64, in which an opening or crack may exit to expose the copper interconnection structure 64.

The invention has looked into the issue about the cobalt cap layer 66a and found that the cleaning process above in FIG. 2 may be not able to provide a surface being well cleaned, which cause the deposition being in poor quality.

After looking into the issues for forming the cobalt cap layer, the invention further proposes an improvement on the pre-cleaning processes, to improve the cleaning surface of the copper interconnection structure 64.

FIG. 3 is a drawing, schematically illustrating the method for fabricating an interconnect structure of semiconductor device, according to an embodiment of the invention.

Referring to FIG. 3, in step S30 as a first stage, the invention performs a pre-sputter clean process with hydrogen radicals on the copper interconnect structure. In this stage, the polishing residues dominated from CuO. The hydrogen radicals (H*) as involved may react with CuO to produce H₂O while Cu is covered. H₂O may be further removed by the degas process as sequentially performed in a second stage. The hydrogen radicals (H*) may also potentially break other components attached to Cu, in which Cu is recovered.

In operation, the degas process in an embodiment is operated at a temperature in a range of 380° C. to 450° C., such as about 400° C. The degas process may include argon gas. In addition, the pre-sputter clean process has a temperature of about 310° C. in an embodiment. The sputter clean process may include a plasma treatment. In an embodiment, the plasma treatment may also include NH₃ plasma.

In the cleaning mechanism, the pre-sputter clean process dominantly cleans moisture and CuO on the copper interconnect structure while hydrogen compounds are not induced yet by the degas process. The degas process may remove moisture and additionally clean hydrogen compound potentially induced by the pre-sputter clean process.

As a result, the Cu surface to be formed with cobalt cap layer 66 is cleaned by the step S30 and the step S32. The step S32 sequentially after the step 30 may remove the moisture and further some weak components to Cu. The Cu surface would be cleaned in better condition.

In step S34, the cobalt material can be deposited with selectivity onto the copper interconnection structure 64 rather than the inter-layer dielectric layer 56. The cleaning quality on the copper interconnection structure 64 can be effectively improved, so the cobalt cap layer 66 can be formed in well condition.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

1. A method for fabricating interconnect of semiconductor device, comprising:
providing a base substrate, having an inter-layer dielectric layer on top;
forming a copper interconnect structure in the inter-layer dielectric layer;
performing a pre-sputter clean process with hydrogen radicals on the copper interconnect structure;
sequentially performing a degas process on the copper interconnect structure; and
forming a cobalt cap layer on the copper interconnect structure.

2. The method of claim 1, wherein the degas process includes argon gas.

3. The method of claim 1, wherein the degas process is operated at a temperature in a range of 380° C. to 450° C.

4. The method of claim 1, wherein the degas process is operated at a temperature of 400° C.

5. The method of claim 1, wherein the step of providing the base substrate comprises:
providing a substrate;
forming the inter-layer dielectric layer over the substrate;
patterning the inter-layer dielectric layer to have an indent structure;
forming a barrier layer on a sidewall and a bottom of the indent structure;
plating a copper layer over the inter-layer dielectric layer, wherein a portion of the copper layer is also filled into the indent structure; and
performing a polishing process until the inter-layer dielectric layer is exposed,
wherein a portion of the copper layer in the indent structure forms the copper interconnect structure.

6. The method of claim 5, further comprising forming a seed layer on the barrier layer before the step of plating the copper layer.

7. The method of claim 5, wherein the indent structure comprises a trench or an opening.

8. The method of claim 1, wherein the pre-sputter clean process comprises forming a plasma containing the hydrogen radicals and filtering the plasma to pass the hydrogen radicals out onto the copper interconnect structure.

9. The method of claim 1, wherein the pre-sputter clean process is performed at a temperature of 300° C. or higher.

10. The method of claim 1, wherein the pre-sputter clean process is performed at a temperature of 310° C.

11. The method of claim 1, wherein the pre-sputter clean process dominantly cleans moisture and CuO on the copper interconnect structure while hydrogen compounds are not induced yet by the degas process.

12. The method of claim 11, wherein the degas process cleans hydrogen compound potentially induced by the pre-sputter clean process.

13. The method of claim 12, wherein the degas process also clean a residue from the polishing process.

14. The method of claim 1, wherein the copper interconnect structure comprises a copper plug.

15. The method of claim 1, wherein the copper interconnect structure comprises an interconnect line.

16. The method of claim 1, wherein the degas process is instantly performed after performing the pre-sputter clean process.
